(19) United States
(12) Patent Application Publication
(10) Pub. No.: US 2009/0133751 A1
(43) Pub. Date: May 28, 2009

(54) Nanostructured Organic Solar Cells

(75) Inventors: Sidlgata V. Sreenivasan, Austin, TX (US); Shrawan Singhal, Austin, TX (US); Christopher Mark Melliar-Smith, Austin, TX (US); Frank Y. Xu, Round Rock, TX (US); Byung-Jin Choi, Austin, TX (US)

Correspondence Address: MOLECULAR IMPRINTS, PO BOX 81536, AUSTIN, TX, 78708-1536, US

(73) Assignees: MOLECULAR IMPRINTS, INC., Austin, TX (US); BOARD OF REGENTS, THE UNIVERSITY OF TEXAS, Austin, TX (US)

(21) Appl. No.: 12/324,120

(22) Filed: Nov. 26, 2008

Related U.S. Application Data
(60) Provisional application No. 60/990,810, filed on Nov. 28, 2007.
(60) Provisional application No. 61/024,597, filed on Jan. 30, 2008.
(60) Provisional application No. 61/111,066, filed on Nov. 4, 2008.

(51) Int. Cl. H01L 31/00

(52) U.S. Cl. 136/256

(57) ABSTRACT

Solar cells having at least one electron acceptor layer and at least one electron donor layer forming a patterned p-n junction are described. Electron acceptor layer may be formed by patterning formable N-type material between a template and an electrode layer, and solidifying the formable N-type material.

### BACKGROUND INFORMATION

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate, therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

An exemplary nano-fabrication technique in use today is commonly referred to as imprint lithography. Exemplary imprint lithography processes are described in detail in numerous publications, such as U.S. Patent Publication No. 2004/0065976, U.S. Patent Publication No. 2004/0065252, and U.S. Pat. No. 6,936,194, all of which are hereby incorporated by reference.

An imprint lithography technique disclosed in each of the aforementioned U.S. patent publications and patent includes formation of a relief pattern in a formable layer (polymerizable) and transferring a pattern corresponding to the relief pattern into an underlying substrate. The substrate may be coupled to a motion stage to obtain a desired positioning to facilitate the patterning process. The patterning process uses a template spaced apart from the substrate and a formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

### BRIEF DESCRIPTION OF DRAWINGS

So that the present invention may be understood in more detail, a description of embodiments of the invention is provided with reference to the embodiments illustrated in the appended drawings. It is to be noted, however, that the appended drawings illustrate only typical embodiments of the invention, and are therefore not to be considered limiting of the scope.

FIG. 1 illustrates a simplified side view of a lithographic system in accordance with an embodiment of the present invention.

FIG. 2 illustrates a simplified side view of the substrate shown in FIG. 1 having a patterned layer positioned thereon.

FIG. 3 illustrates a simplified side view of an exemplary solar cell design.

FIG. 4 illustrates a simplified side view of another exemplary solar cell design.

FIG. 5A illustrates a simplified side view of an exemplary solar cell design having a patterned p-n junction.

FIG. 5B illustrates a simplified side view of another exemplary solar cell design having a patterned p-n junction.

FIG. 6 illustrates a cross-sectional view of an exemplary P-N stack design.

FIG. 7 illustrates a cross-sectional view of another exemplary P-N stack design.

FIG. 8A illustrates a simplified side view of another exemplary solar cell design having multi-tiered and tapered structures.

FIG. 8B illustrates a magnified view of a tapered structure shown in FIG. 8A.

FIG. 9A illustrates a simplified side view of an exemplary P-N stack design having multiple layers.

FIG. 9B illustrates a top down view of the P-N stack design shown in FIG. 9A.

FIGS. 10-16 illustrate an exemplary method for formation of a solar cell having multiple layers.

FIGS. 17-21 illustrate another exemplary method for formation of a solar cell having multiple layers.

FIGS. 22-25 illustrate simplified side views of exemplary N-layer formation from a multi-layer substrate.

### DETAILED DESCRIPTION

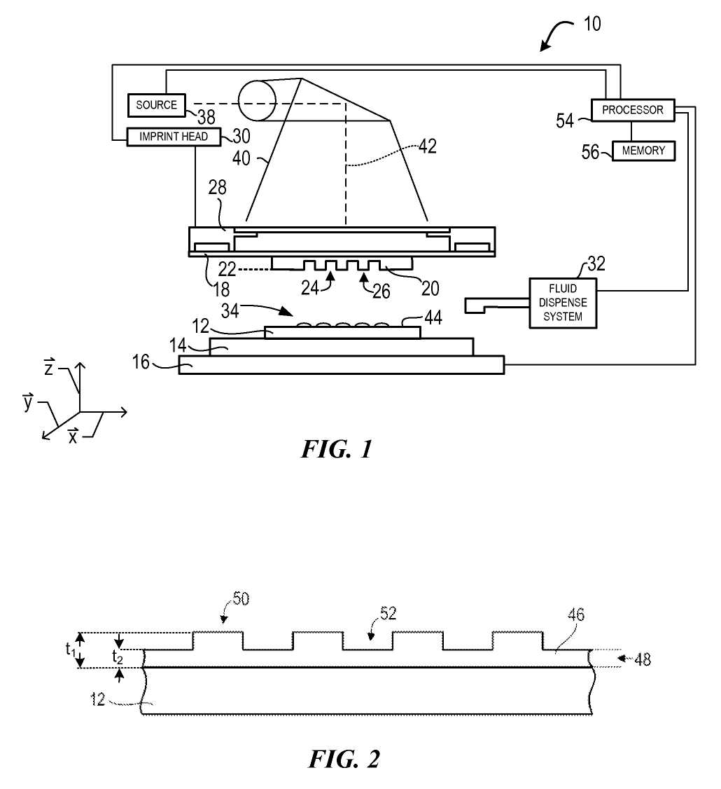

Referring to the figures, and particularly to FIG. 1, illustrated therein is a lithographic system 10 used to form a relief pattern on substrate 12. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electrostatic, electromagnetic, and/or the like. Exemplary chucks are described in U.S. Pat. No. 6,873,087, which is hereby incorporated by reference.

Substrate 12 and substrate chuck 14 may be further supported by stage 16. Stage 16 may provide motion along the x-, y-, and z-axes. Stage 16, substrate 12, and substrate chuck 14 may also be positioned on a base (not shown).

Spaced-apart from substrate 12 is a template 18. Template 18 may include a mesa 20 extending therefrom towards substrate 12, mesa 20 having a patterning surface 22 thereon. Further, mesa 20 may be referred to as mold 20. Alternatively, template 18 may be formed without mesa 20.

Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 comprises features defined by a plurality of spaced-apart recesses 24 and/or protrusions 26, though embodiments of the present invention are not limited to such configurations. Patterning surface 22 may define any original pattern that forms the basis of a pattern to be formed on substrate 12.

Template 18 may be coupled to chuck 28. Chuck 28 may be configured as, but not limited to, vacuum, pin-type, groove-type, electrostatic, electromagnetic, and/or other similar chuck types. Exemplary chucks are further described in U.S. Pat. No. 6,873,087, which is hereby incorporated by reference. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit polymerizable material 34 on substrate 12. Polymerizable material 34 may be positioned upon substrate 12 using techniques such as drop dispense, spin-coating, dip coating, chemical vapor deposition (CVD), physical vapor deposition (PVD), thin film deposition, thick film deposition, and/or the like. Polymerizable material 34 may be disposed upon substrate 12 before and/or after a desired volume is defined between mold 20 and substrate 12 depending on design considerations. Polymerizable material 34 may comprise a monomer mixture as described in U.S. Pat. No. 7,157,036 and U.S. Patent Publication No. 2005/0187339, all of which are hereby incorporated by reference.

Referring to FIGS. 1 and 2, system 10 may further comprise an energy source 38 coupled to direct energy 40 along path 42. Imprint head 30 and stage 16 may be configured to position template 18 and substrate 12 in superimposition with path 42. System 10 may be regulated by a processor 54 in communication with stage 16, imprint head 30, fluid dispense system 32, and/or source 38, and may operate on a computer readable program stored in memory 56.

Either imprint head 30, stage 16, or both vary a distance between mold 20 and substrate 12 to define a desired volume therebetween that is filled by polymerizable material 34. For example, imprint head 30 may apply a force to template 18 such that mold 20 contacts polymerizable material 34. After the desired volume is filled with polymerizable material 34, source 38 produces energy 40, e.g., ultraviolet radiation, causing polymerizable material 34 to solidify and/or cross-link conforming to shape of a surface 44 of substrate 12 and patterning surface 22, defining a patterned layer 46 on substrate 12. Patterned layer 46 may comprise a residual layer 48 and a plurality of features shown as protrusions 50 and recessions 52, with protrusions 50 having thickness t₁ and residual layer having a thickness t₂. It should be noted that solidification and/or cross-linking of polymerizable material 34 may be through other methods including, but not limited, exposure to charged particles, temperature changes, evaporation, and/or other similar methods.

The above-mentioned system and process may be further employed in imprint lithography processes and systems referred to in U.S. Pat. No. 6,932,934, U.S. Patent Publication No. 2004/0124566, U.S. Patent Publication No. 2004/0188381, and U.S. Patent Publication No. 2004/0211754, each of which is hereby incorporated by reference.

### Organic Solar Cell

The availability of low cost nano-patterning may provide organic solar cell designs that substantially improve the efficiency of organic photovoltaic materials. Several resources indicate that the ability to produce nanostructured materials at a reasonable cost may significantly enhance the efficiency of next generation solar cells. See, M. Jacoby, “Tapping the Sun: Basic chemistry drives development of new low-cost solar cells,” Chemical & Engineering News, Aug. 27, 2007, Volume 85, Number 35, pp. 16-22; I. Gur, et al., “Hybrid Solar Cells with Prescribed Nanoscale Morphologies Based on Hyperbranched Semiconductor Nanocrystals,” Nano Lett., 7 (2), 409-414, 2007; G. W. Crabtree et al., “Solar Energy Conversion,” Physics Today, March 2007, pp 37-42; A. J. Nozik, “Exciton Multiplication and Relaxation Dynamics in Quantum Dots: Applications to Ultrahigh-Efficiency Solar Photon Conversion,” Inorg. Chem., 2005, 44, pp. 6893-6899; and, M. Law, et al., “Nanowire dye-sensitized solar cells,” Nature Materials, 4, 455, 2005, all of which are hereby incorporated by reference.

Organic containing non-Si based solar cells may generally be divided into two categories: organic solar cells and inorganic/organic hybrid cells. In organic solar cells, N-type materials may include, but not limited to organic modified fullerene, organic photo harvested dyes coated onto nano-crystal (e.g., TiO₂, ZnO), and/or the like. For example, in forming the N-material from organic modified fullerene, the solar cell may be constructed by a donor-acceptor mechanism using P-material formed of a conjugated polymer. In forming the N-material from organic photo harvested dyes, the dye-sensitized nano-crystal (e.g., TiO₂, ZnO, TiO₂ overcoat ZnO) may be used in conjunction with liquid electrolyte to form the solar cell (also referred to as a Gratzel solar cell).

In inorganic/organic hybrid cells, the P-type material may be formed of organic conjugated polymer and the N-type material may be formed of inorganic materials including, but not limited to TiO₂, CdSe, CdTe, and other similar semiconductor materials.

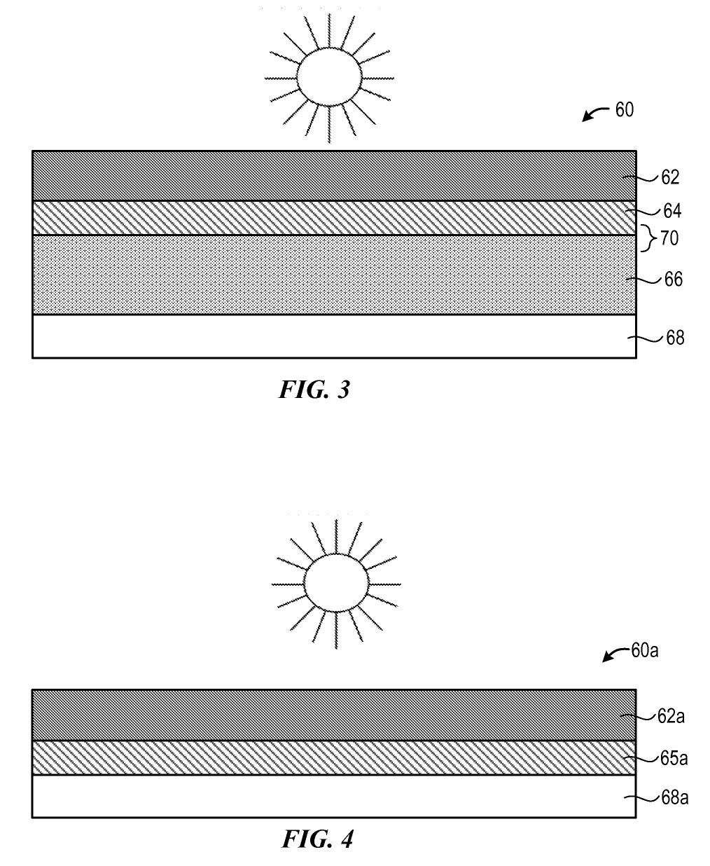

FIG. 3 illustrates a simplified view of an exemplary solar cell design 60 having organic photovoltaic (PV) materials. Generally, the solar cell 60 may include a first electrode layer 62, an electron acceptor layer 64, an electron donor layer 66, and a second electrode layer 68. The solar cell design 60 may include a P-N junction 70 formed by the electron donor layer 66 adjacent to the electron acceptor layer 64.

FIG. 4 illustrates another exemplary solar cell design 60a. This solar cell design 60a may include a first electrode layer 62a, a blended PV layer 65a, and a second electrode layer 68a. Components of this design may be further described in I. Gur, et al., “Hybrid Solar Cells with Prescribed Nanoscale Morphologies Based on Hyperbranched Semiconductor Nanocrystals,” Nano Lett., 7 (2), 409-414, 2007, which is hereby incorporated by reference.

The first electrode layer 62a and second electrode layer 68a of solar cell design 60a may be similar in design to the first electrode layer 62 and second electrode layer 68 of solar cell design 60. The blended PV layer 65a may be formed of PV material blended with N-type inorganic nanoparticles.

Another exemplary solar cell design may incorporate the use of dye sensitized ZnO nanowires. This design is further described in M. Law, et al., “Nanowire dye-sensitized solar cells”, Nature Materials, 4, 455, 2005, which is generally based on Grätzel cells further described in B. O'Regan, et al., “A low-cost, high-efficiency solar cell based on dye-sensitized colloidal TiO₂ films,” Nature 353, 737-740 (1991), both of which are hereby incorporated by reference.

### Optimal and Sub-Optimal Design of Solar Cells

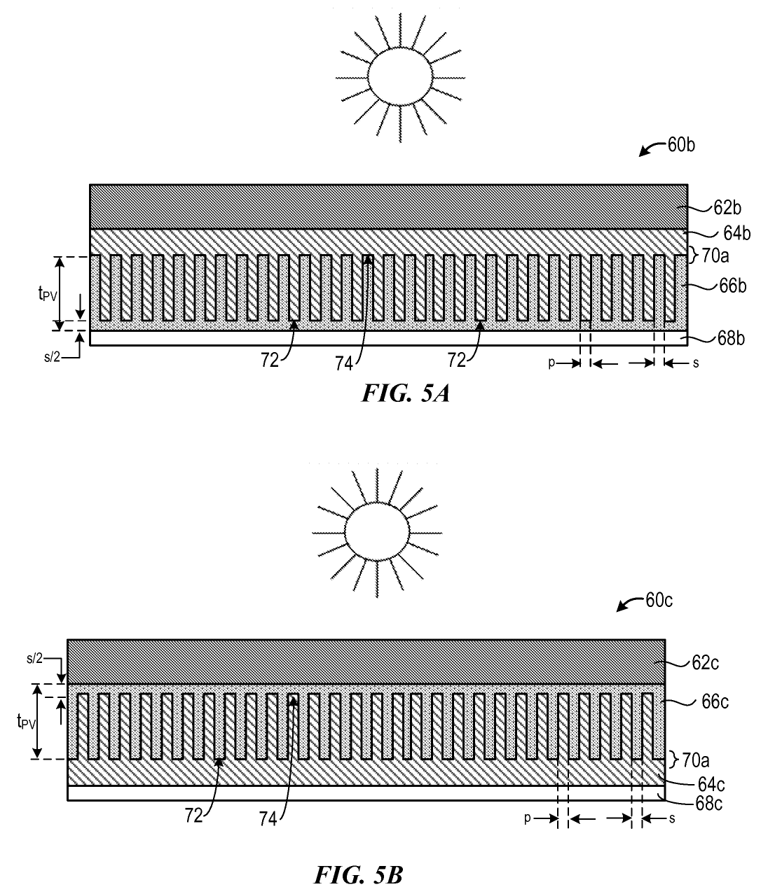

The excitons (electron/hole pairs) created in the PV materials by incident photons may possess a diffusion length L. For example, excitons may posses a diffusion length L that is approximately 5 to 30 nm. Referring to FIG. 3, electron acceptor layer 64 may be patterned to create patterned P-N junctions 70 where the patterned structures approach the diffusion length L providing enhanced exciton capture efficiency. For example, the design of FIG. 3 may be adapted to the design illustrated in FIGS. 5A and/or 5B to increase capture efficiency.

FIGS. 5A and 5B illustrate a simplified views of exemplary solar cells 60b and 60c having a patterned p-n junction 70a. Generally, patterned p-n junction 70a is provided between electron acceptor layer 64b and electron donor layer 66b in FIG. 5A and electron acceptor layer 64c and electron donor layer 66c in FIG. 5B. FIGS. 5A and 5B comprise similar features with FIG. 5A having electron donor layer 66b adjacent to first electrode layer 62b and FIG. 5B having electron donor layer 66c adjacent to first electrode layer 62c. For simplicity, the following describes solar cell 60b in FIG. 5A, however, one skilled in the art will appreciate the similarities and distinctions to solar cell 60c.

Referring to FIG. 5A, to form solar cell 60b, the electron donor layer 66b may be imprinted over the second electrode layer 68b. The electron acceptor layer 64b may then be imprinted over the electron donor layer 66b. Alternatively, formation of solar cell 60b may include imprinting electron acceptor layer 64b on first electrode layer 62b and depositing electron donor layer 66b on electron acceptor layer 64b. Exemplary imprinting processes are further described in 1. McMackin, et al., “Patterned Wafer Defect Density Analysis of Step and Flash Imprint Lithography,” Under Review, Journal of Vacuum Science and Technology B: Microelectronics and Nanostructures; S. Y. Chou, et al., “Nanoimprint Lithography”, J. Vac. Sci. Technol. B 14(6), 1996; H. Tan, et al., “Roller nanoimprint lithography”, J. Vac. Sci. Technol. B 16(6), 1998; B. D. Gates, et al., “New Approaches to Nanofabrication: Molding, Printing, and Other Techniques”, Chem. Rev., 105, 2005; S. Y. Chou, et al., “Lithographically induced self-assembly of periodic polymer micropillar arrays”, J. Vac. Sci. Technol. B, 17(6), 1999; S. Y. Chou, et al., “Ultrafast and direct imprint of nanostructures in silicon”, Nature, 417, 2002; K. H. Hsu, et al., “Electrochemical Nanoimprinting with Solid-State Superionic Stamps”, Nano Lett., 7(2), 2007; and W. Srituravanich, et al., “Plasmonic Nanolithography”, Nano Lett., 4(6), 2004, all of which are hereby incorporated by reference.

The first electrode layer 62b and second electrode layer 68b are generally conductive and may be formed of materials including, but not limited to, indium tin oxide, aluminum, and the like. At least a portion of the first electrode layer 62b may be substantially transparent. Additionally, the first electrode layer 62b may be formed as a metal grid. The metal grid may increase the total area of the solar cell 60b having exposure to energy (e.g., the sun). Metals may be directly patterned using processes such as described in K. H. Hsu, et al., “Electrochemical Nanoimprinting with Solid-State Superionic Stamps”, Nano Lett., 7(2), 2007.

The electron acceptor layer 64b may be formed of N-type materials including, but not limited to, fullerene derivatives and the like. Fullerene may be organically modified to attach functional groups such as thiophene for electro-polymerization. Additionally, fullerene may be modified to attach functional groups including, but not limited to, acrylate, methacrylate, thiol, vinyl, and epoxy, that may undergo crosslinking upon exposure to UV and/or heat. Additionally, fullerene derivatives may be imprinted by adding a small amount of crosslinkable binding materials.

The electron donor layer 66b may be formed of P-type materials including, but not limited to, polythiophene derivatives (e.g., poly 3-hexylthiophene), polyphenylene vinylene derivatives (e.g., MDMO-PPV), poly-(thiophene-pyrrole-thiophene-benzothiadiazole) derivatives, and the like. Generally, the main chain conjugated backbones of these polymers may be unaltered. The side chain derivatives, however, may be altered to incorporate reactive functional groups that may undergo a crosslinking reaction upon exposure to UV and/or heat including, but not limited to, acrylate, methacrylate, thiol, vinyl, and epoxy. See, K. M. Coakley, et al., “Conjugated Polymer Photovoltaic Cells,” Chem. Mater., ACS Publications, 2004, 16, pp. 4533-4542, which is hereby incorporated by reference. The addition of semiconductor nanocrystals including, but limited to, cadmium selenide and cadmium telluride, ZnO nanowires with or without TiO2 coatings, and the like, may further improve efficiencies of the PV materials.

Fullerene derivatives and polysilicon may be deposited using ink jet techniques as described in T. Shimoda, et al. “Solution-processed silicon films and transistors,” Nature, 2006, 440, pp. 783-786, which is hereby incorporated by reference. Depositing using ink jet techniques may allow for low cost, non vacuum deposition. Silicon based lithographic processes with sacrificial resists and reactive ion etching (RIE) may be used to etch doped polysilicon type materials. Additionally, silicon based lithographic processes, including reactive ion etching, may allow for the use of high aspect ratio patterned pillars using intermediate hard masks (e.g., SiN).

Dyes may also be added to improve broadband absorption of photons and provide efficiencies in the range of approximately 1-3%. See, M. Jacoby, “Tapping the Sun: Basic chemistry drives development of new low-cost solar cells,” Chemical & Engineering News, Aug. 27, 2007, Volume 85, Number 35, pp. 16-22, which is hereby incorporated by reference.

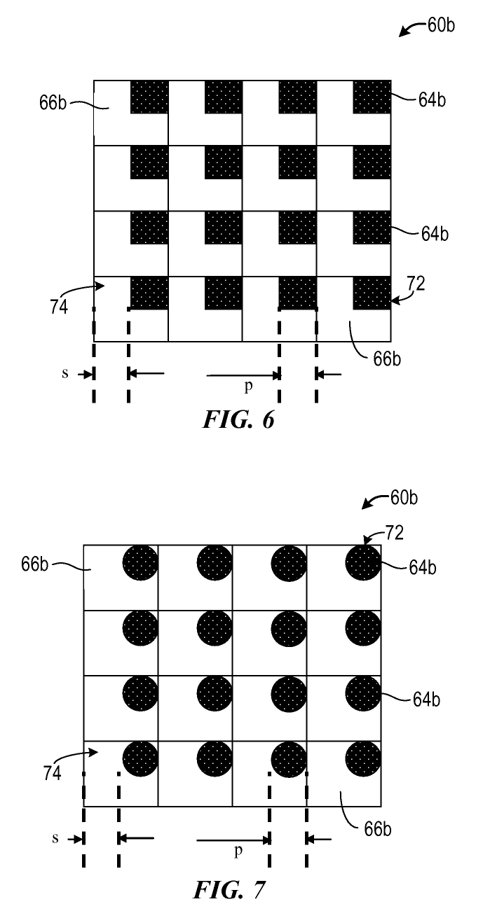

Electron donor layer 66b may have a thickness t_{PV}. For example, the thickness t_{PV} of electron donor layer 66b may be approximately 100-500 nm. The electron acceptor layer 64b may be patterned to possess one or more pillars 72 having a length p. FIG. 5A illustrates electron acceptor layer 64b having multiple pillars 72. Pillars 72 may have a cross-sectional square, circular, rectangular, or any other fanciful shape. For example, FIG. 6 illustrates a cross-sectional view of pillars 72 having a square shape and FIG. 7 illustrates a cross-sectional view of pillars 72 having a circular shape. Adjacent pillars 72 may form one or more recesses 74 each having a length s.

Referring to FIGS. 5A and 6, the volume reduction within the electron donor layer 66b may be a function of the values of the length p of the pillar 72 and the length s of the recess 74. For example, if the length p of the pillar 72 is substantially equal to the length s of the recess 74, then the volume of the electron donor layer 66b may be reduced by 25% due to the patterned electron acceptor layer 64b interface with the electron donor layer 66b (i.e., the patterned P-N junction 70a).

In one embodiment, recesses 74 may be provided with length s=2L and pillars 72 may be provided with length p<2L, wherein L is the diffusion length of the electrons created in the electron donor layer 66b. This reduction in the length p of pillars 72 may provide for a high volume of electron donor layer 66b for a given thickness t_{PV} of the electron donor layer 66b. For example, if L=10 nm, then s=20 nm and p<20 nm. With a thickness t_{PV} of 200 nm, the pillars 72 may have a 20:1 aspect ratio. A 20:1 aspect ratio, however, may be difficult to fabricate reliably and inexpensively due to mechanical stability.

Sub-optimal designs may be implemented. For example, if the diffusion length L is approximately 10 nm, the length p of pillar 72 may be designed at approximately 50 nm with length s of recess 74 set at approximately 100 nm. For a thickness t_{PV} of 200 nm, pillars 72 may have about a 4:1 ratio. Additionally, the lost volume of the electron donor layer 66b may be approximately 8.7% as compared to 25% in the optimal design.

Sub-optimal designs, however, may have lower capture efficiency. As such, sub-optimal designs may be complemented with blended PV materials in the electron donor layer 66b, wherein the electron donor layer 66b may contain conjugated polymers mixed with inorganic nano-rods, as described in 1. Gur, et al., “Hybrid Solar Cells with Prescribed Nanoscale Morphologies Based on Hyperbranched Semiconductor Nanocrystals,” Nano Lett., 2007, 7(2), pp. 407-414; and, W. U. Huynh, et al., “CdSe nanocrystal Rods/Poly(3-hexylithiophene) Composite Photovoltaic Devices,” Adv. Mater., 1999, 11(11) pp. 923-927. Exemplary blended materials include, but are not limited to, mixtures of 5 nm diameter CdSe nanocrystals and Meh-PPv poly(2-methoxy-5-(2′-ethyl-hexyloxy)-p-phenylenevinylene), and 8×13 nm elongated CdSe nanocrystals and regi-regular poly(3-hexylithiophene) (P3HT). Such blended materials may substantially overcome the lost exciton capture potential due to the departure from the optimal geometry of the patterned P-N junction 70a discussed above.

### ZnO Patterned Dots

ZnO may be patterned using dots rather than ZnO nanoparticles. Patterning may improve placement and uniformity as compared to ZnO nanoparticles further described in Coakley, “Conjugated Polymer Photovoltaic Cells,” Chem. Mater., ACS Publication, 2004, 16, pp. 4533-4542, which is hereby incorporated by reference. For example, patterning may be provided followed by a reactive ion etching as further described in Zhu, “SiCl₄-Based Reactive Ion Etching of ZnO and MgₓZn₁₋ₓ Films on r-Sapphire Substrates,” J. of Electronic Mater., 2006, 35:4, which is hereby incorporated by reference. Patterning using reactive ion etching may provide for substantially precise placement in addition to size control.

### Three-Dimensional Patterning

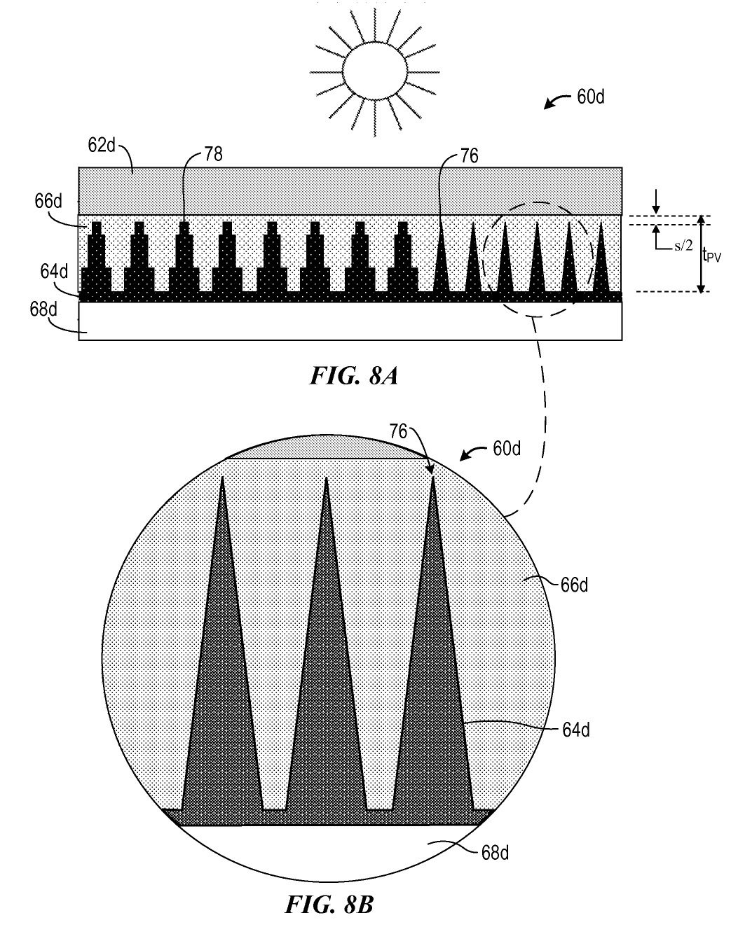

FIGS. 8A and 8B illustrate exemplary solar cell designs 60d and 60e having tapered structures 76 and/or multi-tiered structures 78. Tapered structures 76 and/or multi-tiered structures 78 may increase mechanical stability of high aspect ratio structures. Such structures may be sub-optimal with respect to maximum exciton capture; however, when used in conjunction with blended materials (as discussed herein) may lead to higher efficiency solar cells 60 with thick PV films.

As illustrated in FIG. 8B, the design of the tapered structure 76 may be substantially conical. Generally, the reflection of solar photon may be increased at steep angles of incidence. This may cause photons to take a longer path through electron donor layer 66d with an increase in the probability of photons being absorbed.

Additionally, materials at the air interface may assist in cycling photons through electron donor layer 66b. For example, as previously discussed, materials at the air interface may include, but are not limited to, fullerene derivatives, ITO, conjugated polymers and TiO₂. Each of these materials include high indexes ranging from approximately 1.5 (e.g., polymers) to greater than approximately 2 (e.g., fullerenes). As such, light approaching the air interface at inclination exceeding the critical angle may internally reflect. If the first electrode layer 62d is a metal contact grid, this may assist with cycling photons back through electron donor layer 66d.

### Dual Patterning

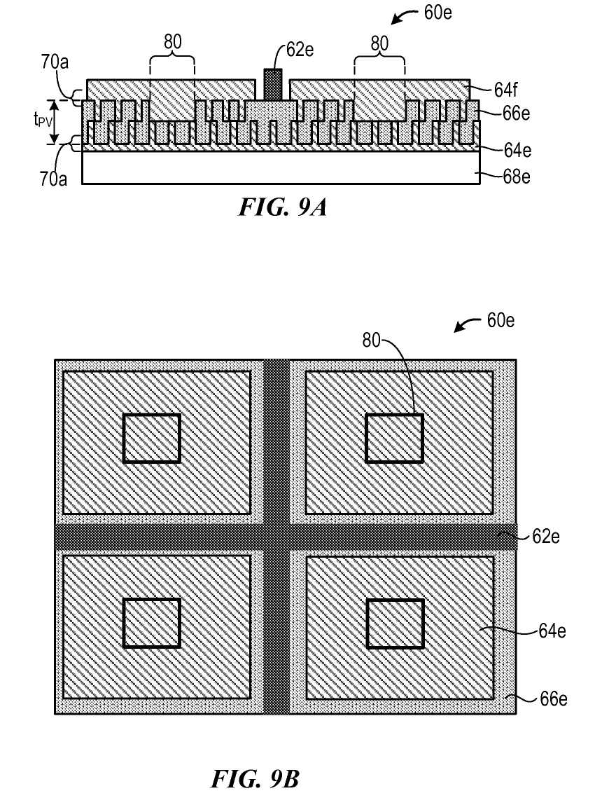

FIGS. 9A and 9B illustrate a solar cell design 60e having multiple electron acceptor layers 64e and 64f. Each electron acceptor layer 64e and 64f may include pillars 72. Pillars 72 may protrude into electron donor layer 66e forming multiple patterned p-n junctions 70a between electron donor layer 66e and electron acceptor layers 64e and 64f. Electron acceptor layers 64e and 64f may be connected by a pad 80. Pad 80 may be formed of N-type materials. Additionally, pad 80 may be formed of similar materials to electron acceptor layer 64e and/or 64f.

The first electrode layer 62e may be adjacent to electron donor layer 66e. The first electrode layer 62e may also be isolated from electron acceptor layer 64e and/or 64f.

Solar cell design 60e may be patterned using dual patterning steps. Dual patterning steps may nominally double the area of the patterned p-n junction 70a and the thickness t_{PV} of the electron donor layer 66e. Using imprinting, a thin PV material film (e.g., <10 nm) may remain and may prevent direct contact between pad 80 and underlying pillars 72 of electron acceptor layer 64e. The thin PV material film may be even further reduced (e.g., <5 nm) to provide for conductivity between the electron acceptor layer 64e and electron acceptor layer 64f.

### Solar Cell Formation Utilizing Multiple Layers

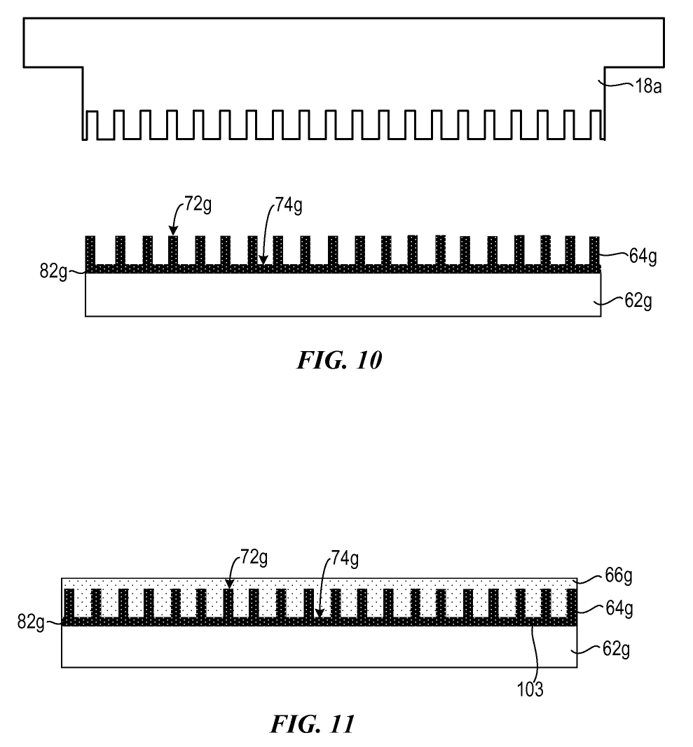

FIGS. 10-16 illustrate simplified side views of exemplary formation of a solar cell 60g utilizing multiple layers of N-type material and P-type material. In providing multiple layers of N-type material and P-type material, different layers may be formed of similar material and/or different material. For example, as is well known in the art, the absorption range of P-type materials varies across the solar spectrum. As such, by using layers formed of different P-type material, solar cell 60g may be able to provide a greater range of absorption across the solar spectrum. For example, electron donor layer 66g may be formed of material including P3HT having an absorption range between approximately 300-600 λ/nm. To provide a greater range of absorption across the solar spectrum, electron donor layer 66h may be formed of material including MDMO-PPV having an absorption range between approximately 600-700 λ/nm; as a result, solar cell 60g may be able to provide an absorption range of approximately 300-700 λ/nm.

Referring to FIG. 10, electron acceptor layer 64g may be formed on a first electrode layer 62g. Electron acceptor layer 64g may be formed by techniques, including, but not limited to, imprint lithography, photolithography (various wavelengths including G line, I line, 248 nm, 193 nm, 157 nm, and 13.2-13.4 nm), interferometric lithography, contact lithography, e-beam lithography, x-ray lithography, ion-beam lithography, and atomic beam lithography. For example, electron acceptor layer 64g may be formed using imprint lithography as described herein and in U.S. Pat. No. 6,932,934, U.S. Patent Publication No. 2004/0124566, U.S. Patent Publication No. 2004/0188381, and U.S. Patent Publication No. 2004/0211722, all of which are hereby incorporated by reference. Electron acceptor layer 64g may be patterned by template 18a to provide pillars 72g and a residual layer 82g. Pillars 72g may be on the nanometer scale. Recesses 74g between pillars 72g maybe on the order of the diffusion length L (e.g., 5-10 nm).

Referring to FIG. 11, electron donor layer 66g may be positioned over pillars 72g of electron acceptor layer 64g. This may be achieved by methods including, but not limited to, spin-on techniques, contact planarization, and the like.

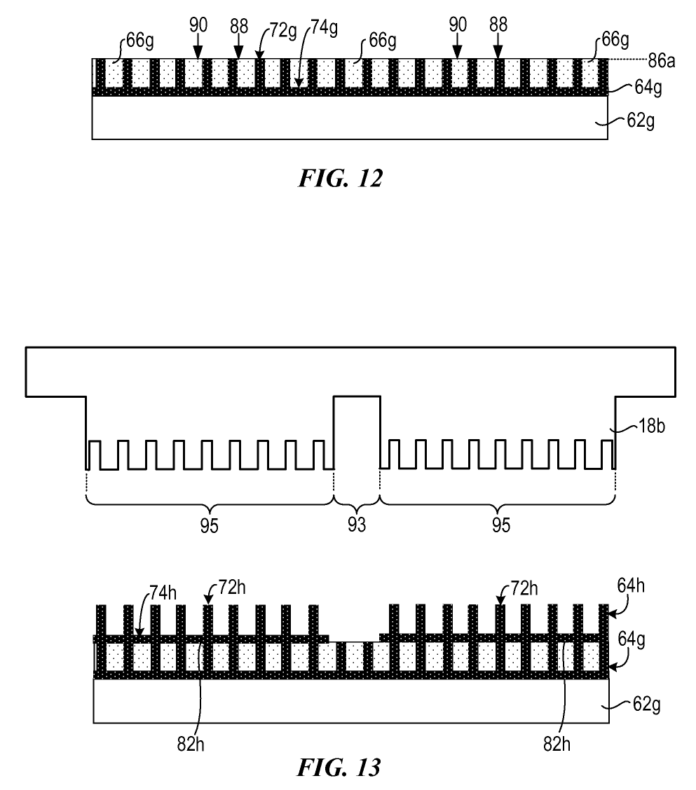

Referring to FIG. 12, a blanket etch may be employed to remove portions of electron donor layer 66g. The blanket etch may be a wet etch or dry etch. In a further embodiment, a chemical mechanical polishing/planarization may be employed to remove portions of electron donor layer 66g. Removal of portions of electron donor layer 66g may provide a crown surface 86a. Crown surface 86a generally comprises the surface 88 of at least a portion of each pillar 72g and the surface 90 of at least a portion of electron donor layer 66g.

Referring to FIG. 13, a second electron acceptor layer 64h may be provided. The second electron acceptor layer 64h may be patterned having pillars 72h and residual layer 82h forming recesses 74h. Pillars 72h and recesses 74h may be on the order of the diffusion length L, 5-10 nm, as described above.

Second electron acceptor layer 64h may be formed by template 18b using imprint lithography or other methods, as described above. Template 18b may include a patterning region 95 and a recessed region 93, with patterning region 95 surrounding recessed region 93. As a result of recessed region 93 of template 18b, second electron acceptor layer 64h may be non-contiguous. For example, second electron acceptor layer 64h may not be in superimposition with recessed region 93 resulting from capillary forces between any of the material of second electron acceptor layer 64h, template 18b, and/or electron acceptor layer 64g, as further described in U.S. Patent Publication No. 2005/0061773, which is hereby incorporated by reference. Generally, the non-contiguous portion of the second electron acceptor layer 64h may result in minor loss of electron capture due to lack of matrix of the N-type material. Electron acceptor layer 64g may also be formed non-contiguous depending on design considerations.

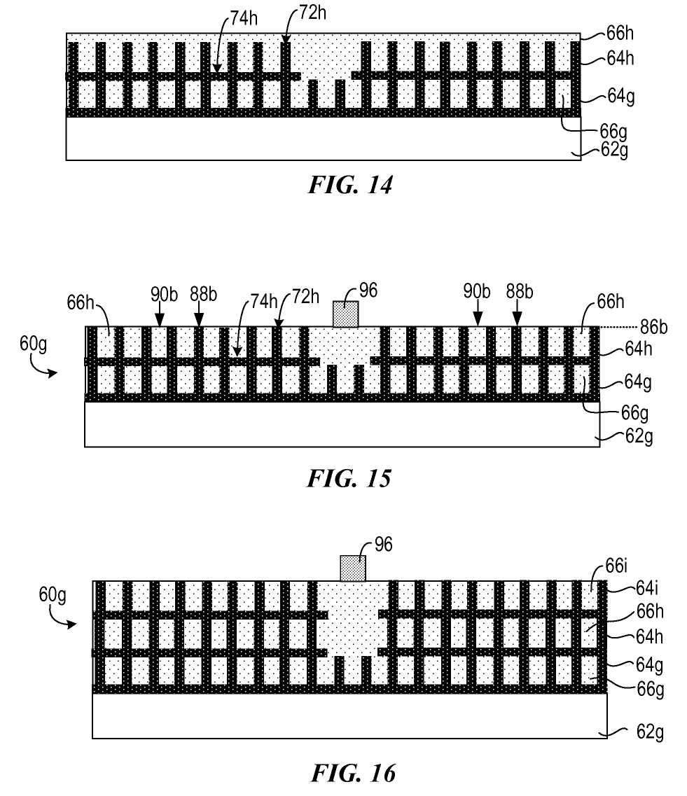

Referring to FIG. 14, a second electron donor layer 66h may be positioned over pillars 72h. The second electron donor layer 66h may be formed employing any of the techniques mentioned above with respect to the first electron donor layer 66g.

Referring to FIG. 15, a blanket etch may be employed to remove portions of the second electron donor layer 66h to provide a crown surface 86b. Crown surface 86b is defined by at least a portion of surface 88b of each of pillar 72h and at least a portion of surface 88b of second electron donor layer 66h. The blanket etch may be a wet etch or dry etch. In a further embodiment, a chemical mechanical polishing/planarization may be employed to remove at least a portion of second electron donor layer 66h to provide crown surface 86b. The second electron acceptor layer 64h and the electron acceptor layer 64g may be in electrical communication in electrical communication with electrode layer 62g. Further, the second electron donor layer 66h may be in electrical communication with electron donor layer 66g, and both may be in electrical communication with electrode 96.

Solar cell 60g may be subjected to substantially the same process described above to form additional electron donor and electron acceptor layers. For example, in FIG. 16, three electron acceptor layers 64g-i and three electron donor layers 66g-i are illustrated; however, it should be appreciated by one skilled in the art that any number of layers may be formed depending on design considerations.

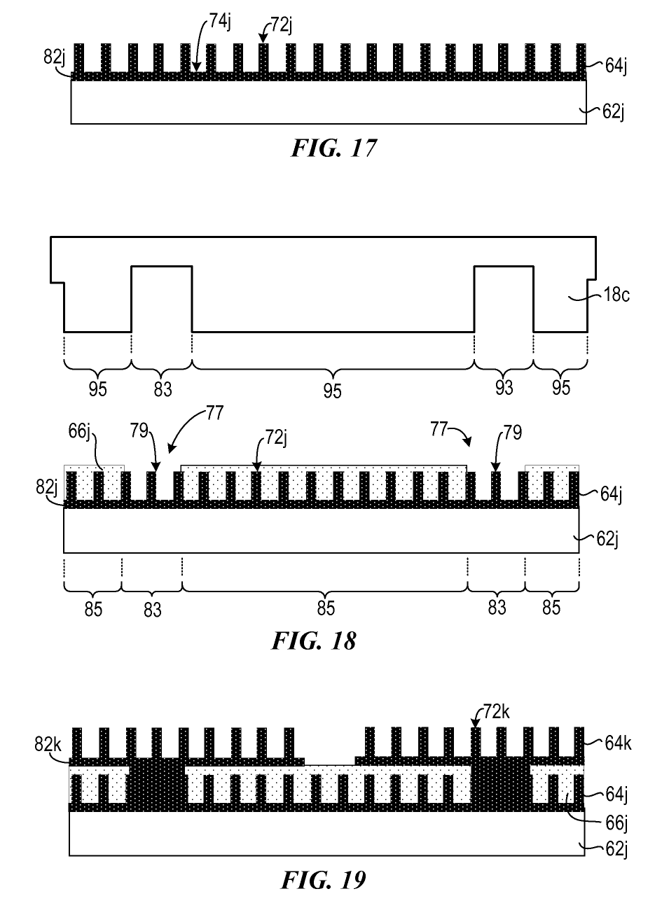

FIGS. 17-21 illustrate simplified side views of exemplary formation of another solar cell 60j utilizing multiple layers.

Referring to FIG. 17, electron acceptor layer 64j may be patterned on electrode layer 62j. Electron acceptor layer 64j may comprise pillars 72j and a residual layer 82j. Pillars 72j and residual layer 82j may form recesses 74j. The length s of recesses 74j may be on the order of the diffusion length L, 5-10 nm, as described in detail above. Electron acceptor layer 64j may be substantially the same as electron acceptor layer 64g described in detail above with respect to FIGS. 10-16, and may be formed in substantially the same manner.

Referring to FIG. 18, electron donor layer 66j may be positioned over at least a portion of electron acceptor layer 64j by techniques including, but not limited to, chemical vapor deposition (CVD), physical vapor deposition (PVD), spin coating, and drop dispense techniques. Electron donor layer 66j may be patterned by template 18c having patterning regions 93 and recessed regions 95. For example, recessed regions 95 of template 18c may be on the micron scale. During imprinting, patterning regions 93 and recessed regions 95 of template 18c may form first region 83 and second region 85 of electron donor layer 66j from capillary forces, as mentioned above, between electron donor layer 66j, template 18c, electrode layer 62j, and/or electron acceptor layer 64j. As such, at least a portion of the surface 79 of pillars 72j may be exposed, defining unfilled region 77.

Referring to FIG. 19, a second electron acceptor layer 64k may be positioned on electron donor layer 66j. The second electron acceptor layer 64k may be patterned having pillars 72k and residual layer 82k. The second electron acceptor layer 64k may be substantially the same as electron acceptor layer 64j described above, and may be formed in substantially the same manner.

The spacing between residual layer 82k of second electron acceptor layer 64k and residual layer 82j of electron acceptor layer 64j may be on the order of the diffusion length L, 5-10 nm. Further, the second electron acceptor layer 64k may be positioned within unfilled region 77. As a result, the second electron acceptor layer 64k may be coupled to electron layer 64j with both in electrical communication with electrode layer 62j.

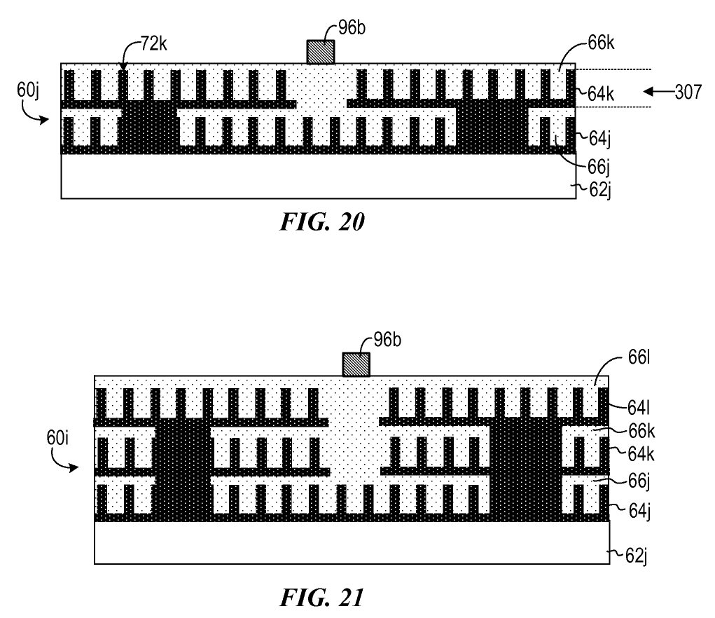

Referring to FIG. 20, a second electron donor layer 66k may be positioned over pillars 72k. The second electron donor layer 66k may be similar to electron donor layer 66j described in detail above and may be formed in substantially the same manner. Further, the second electron donor layer 66k may be in electrical communication with electron donor layer 66j with both in electrical communication with electrode 96b.

Solar cell 60j may be subjected to substantially the same process described above to form additional electron donor and electron acceptor layers. For example, in FIG. 21, three electron acceptor layers 64j-l and three electron donor layers 66j-l are illustrated; however, it should be appreciated by one skilled in the art that any number of layers may be formed depending on design considerations.

### Solar Cell Design Utilizing Patterning Followed by Conformal Thin Coating of Active Material

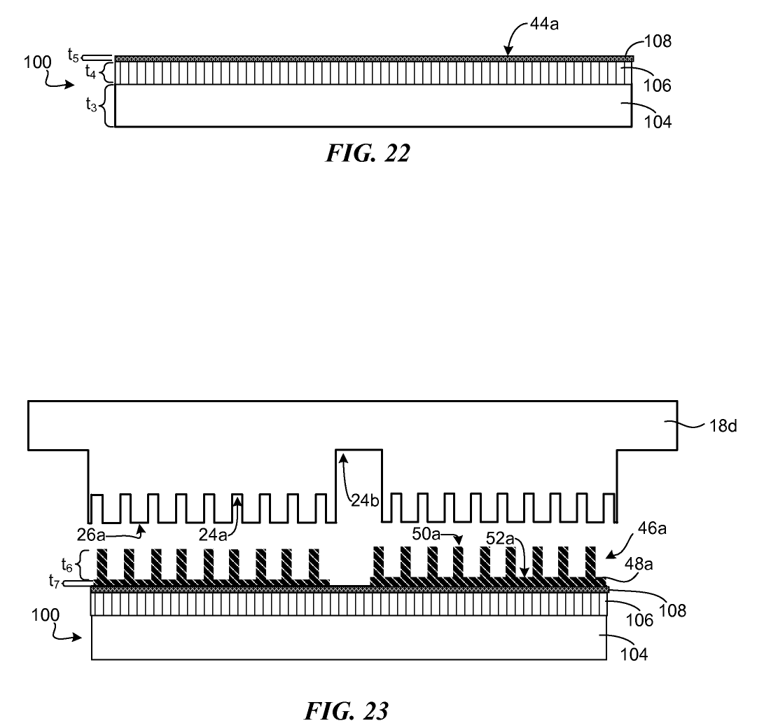

FIGS. 22-25 illustrate simplified side views of exemplary electron acceptor layer 64m formation from a multi-layer substrate 100. Generally, multi-layer substrate 100 may be formed of a substrate layer 104, an electrode layer 106, and an adhesive layer 108. Patterned layer 46a may be formed by template 18d having primary recesses 24a and secondary recesses 24b. Primary recesses 24a assist in providing patterned layer 46a with features including protrusions 50a and recessions 52b. Secondary recesses 24b assist in providing electron acceptor layer 64m with one or more gaps 102. A conformal coating 110 may be deposited on patterned layer 46a and the gaps 102 may be distributed to facilitate a charge transfer between conformal coating 110 and electrode layer 106.

As illustrated in FIG. 22, multi-layer substrate 100 may be formed of substrate layer 104, electrode layer 106, and adhesive layer 108. Substrate layer 104 may be formed of materials including, but not limited to, plastic, fused-silica, quartz, silicon, organic polymers, siloxane polymers, borosilicate glass, fluorocarbon polymers, metal, hardened sapphire, and/or the like. Substrate layer 104 may have a thickness t₃. For example, substrate layer 104 may have a thickness t₃ of approximately 10 μm to 10 mm.

Electrode layer 106 may be formed of materials including, but not limited to, aluminum, indium tin oxide, and the like. The electrode layer 106 may have a thickness t₄. For example, the electrode layer 106 may have a thickness t₄ of approximately 1 to 100 μm.

Adhesive layer 108 may be formed of adhesion materials as further described in U.S. Publication No. 2007/0212494, which is hereby incorporated by reference. Adhesive layer 108 may have a thickness t₅. For example, adhesive layer 108 may have a thickness t₅ of approximately 1-10 nm.

As illustrated in FIG. 23, patterned layer 46a may be formed between template 18d and multi-layer substrate 100 by solidification and/or cross-linking of formable N-type material to conform to shape of a surface 44a of multi-layer substrate 100 and template 18d. Patterned layer 46a may comprise a residual layer 48a and the features shown as protrusions 50a and recessions 52a. Protrusions 50a may have a thickness t₆ and residual layer may have a thickness t₇. Residual layer may have a thickness t₇ of approximately 10 nm-500 nm. The spacing and height of protrusions 50a may be based on optimal and/or sub-optimal designs to form pillars 72. For example, thickness t₆ of protrusions 50 may be on the 50-500 nanometer scale with the spacing of protrusions 50a on the order of the diffusion length L (e.g., 5-50 nm).

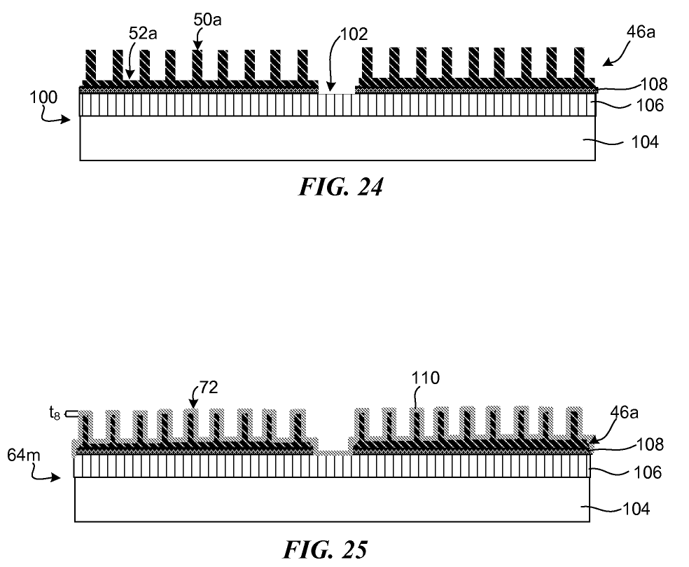

Additionally, patterned layer 46a may have one or more gaps 102. The size of the gaps 102 and number of gaps 102 may be such that gaps 102 do not consume more than 1-10% of the total area of the multi-layer substrate 100. As illustrated in FIG. 24, adhesive layer 108 within gap 102 may be removed by an oxidization step. For example, adhesive layer 108 within gap 102 may be removed by an oxidization step having no substantial impact on the shape and size of the patterned layer 46a. (e.g., UV ozone or other plasma process, or a short exposure to oxidizing wet process such as sulfuric acid).

As illustrated in FIG. 25, a conformal coating 110 may be deposited on patterned layer 46a and gap 102 to form electron acceptor layer 64m having pillars 72. Conformal coating 110 may be formed of N-type materials as discussed herein. Such N-type materials (e.g., fullerene C60) may be vapor deposited by sublimation. For example, such N-type materials may be deposited by physical vapor deposition at room temperature in a vacuum chamber at 10-6 torr using C60 powder. In another example, such N-type materials (e.g., fullerene) may be deposited with an e-beam evaporator loaded with commercially available fullerene powder.

Conformal coating 110 may have a thickness t₈. For example, conformal coating 110 may have a thickness of approximately 1-10 nm. As illustrated, conformal coating 110, by way of gap 102, may be in direct communication with electrode layer 104.

It should be noted that an N-type conformal coating may then be further coated or deposited using ink jet with a P-type material. P-type material may include, but is not limited to, polythiophene derivatives, polyphenylene vinylene derivatives, poly-(thiophene-pyrrole-thiophene-benzothiadiazole) derivatives, and the like as discussed herein. This may be followed by the fabrication of a top conductor leading to a solar cell similar to the one in FIG. 5B.

The distance between the gaps 102 and the size of the gaps 102 may be selected, to not only minimize loss of device area (as discussed earlier), but also may address a competing requirement: minimization of the distance traveled by the charged particle to the bottom electrode, wherein the charged particle is created by disassociation of the exciton at the patterned P-N interface.

What is claimed is:

1. A solar cell comprising:
a first electron acceptor layer formed by patterning formable N-type material between a first template having sub-100 nanometer resolution and a first electrode layer, and solidifying the N-type material, the first electron acceptor layer having a plurality of pillars and a plurality of recesses; and,
a first electron donor layer deposited on at least a portion of the first electron acceptor layer, the first electron donor layer and the first electron acceptor layer forming at least one patterned p-n junction.

2. The solar cell of claim 1 wherein at least one pillar of the first electron acceptor layer is tapered.

3. The solar cell of claim 2 wherein the tapered pillar is substantially conical.

4. The solar cell of claim 1 wherein at least one pillar of the first electron acceptor layer is formed of at least two tiers.

5. The solar cell of claim 1 further comprising a second electrode layer formed on the first electron donor layer.

6. The solar cell of claim 5 wherein the second electrode layer is a metal grid.

7. The solar cell of claim 1 further comprising:
a second electron acceptor layer formed by patterning a second formable N-type material between a second template and the first electron donor layer and solidifying the second formable N-type material, the second electron acceptor layer having a plurality of pillars and a plurality of recesses.

8. The solar cell of claim 7 further comprising a pad formed of third N-type material connecting first electron acceptor layer to second electron acceptor layer.

9. The solar cell of claim 8 further comprising a photovoltaic material layer positioned between the pad and the first electron acceptor layer.

10. The solar cell of claim 9 further comprising a photovoltaic material layer positioned between the pad and the second electron acceptor layer.

11. The solar cell of claim 7 wherein the first electron donor layer and the second electron donor layer are in electrical communication with the first electrode layer.

12. The solar cell of claim 7 further comprising a second electron donor layer deposited on the second electron acceptor layer.

13. The solar cell of claim 12 wherein the first electron donor layer is formed of material having a first absorption range and the second electron donor layer is formed of material having a second absorption range, wherein the first absorption range is different from the second absorption range.

14. The solar cell of claim 1 wherein the first electron acceptor layer is non-contiguous forming at least one gap.

15. The solar cell of claim 14 wherein first electron acceptor layer includes a conformal coating deposited on the gap such that the conformal coating is in electrical communication with the first electrode layer.

16. The solar cell of claim 1 wherein at least one pillar is further defined by a length of less than approximately twice the diffusion length of excitons.

17. The solar cell of claim 1 wherein at least one pillar is further defined by a length less than the diffusion length of excitons.

18. The solar cell of claim 1 wherein the recesses are sequentially interspersed between the pillars.

19. The solar cell of claim 18 wherein first electron donor layer is deposited within recesses of the first electron acceptor layer.

20. A solar cell comprising:
an electron donor layer;
an electron acceptor layer adjacent to the electron donor layer forming a patterned p-n junction for diffusion of excitons having a diffusion length L, the electron acceptor layer comprising:
a plurality of pillars, at least one pillar defined by a length of less than approximately 2L; and,
a plurality of recesses, at least one recess defined by a length of approximately 2L.

21. A solar cell comprising:
a first electrode layer;
a first electron acceptor layer comprising:
a multi-layer substrate having at least one non-contiguous gap formed by patterning formable N-type material between a first template and first electrode layer and solidifying the N-type material, the multi-layer substrate having a plurality of recesses sequentially interspersed with a plurality of pillars; and,
a conformal coating deposited on the multi-layer substrate such that the conformal coating is in electrical communication with the first electrode layer;
a first electron donor layer deposited on the first electron acceptor layer and in recesses formed in the first electron acceptor layer, the first electron donor layer deposited to form a patterned p-n junction between the first electron donor layer and the first electron acceptor layer; and,
a second electrode layer deposited on the first electron donor layer.

22. A multi-layer structure providing electrical communication between interconnected N-type and P-type material, comprising:
a first electrode layer;
a plurality of electron acceptor layers formed of formable N-type material, at least one electron acceptor layer formed by patterning the formable N-type material between a first template having sub-100 nanometer resolution and the first electrode layer and solidifying the N-type material, the electron acceptor layers having a plurality of pillars and a plurality of recesses;
a plurality of electron donor layers, the electron donor layers sequentially interspersed with the electron acceptor layers, each electron donor layer having an absorption range within the solar spectrum;
a second electrode layer positioned adjacent to at least one electron donor layer.

23. The multi-layer structure of claim 22 wherein at least two electron donor layers have different absorption ranges within the solar spectrum.
